(19) United States
(12) Patent Application Publication
(10) Pub. No.: US 2019/0097602 A1
(43) Pub. Date: Mar. 28, 2019

(54) ELASTIC WAVE DEVICE

(71) Applicant: Murata Manufacturing Co., Ltd., Nagaokakyo-shi (JP)

(72) Inventor: Tetsuya KIMURA, Nagaokakyo-shi (JP)

(21) Appl. No.: 16/125,801

(22) Filed: Sep. 10, 2018

(30) Foreign Application Priority Data
Sep. 27, 2017 (JP) 2017-186483

(51) Int. Cl. H03H 9/02; H03H 9/145; H03H 9/25; H03H 9/64

(52) U.S. Cl. CPC H03H 9/02866; H03H 9/02559; H03H 9/02637; H01L 41/0477; H03H 9/25; H03H 9/6489; H03H 9/145

(57) ABSTRACT

In an elastic wave device that utilizes longitudinal wave leaky elastic wave, an IDT electrode is provided on a first or second principal surface of a piezoelectric layer, an energy confinement layer that is laminated on the second principal surface of the piezoelectric layer so as to support the piezoelectric layer and confines energy of the longitudinal wave leaky elastic wave into the piezoelectric layer is provided, a thickness of the piezoelectric layer is λ or less when λ represents a wavelength determined according to an electrode finger pitch of the IDT electrode, and a groove is provided in at least one of the first and second principal surfaces of the piezoelectric layer, and the IDT electrode includes a portion in the groove.

### CROSS REFERENCE TO RELATED APPLICATIONS

This application claims the benefit of priority to Japanese Patent Application No. 2017-186483 filed on Sep. 27, 2017. The entire contents of this application are hereby incorporated herein by reference.

### BACKGROUND OF THE INVENTION

### 1. Field of the Invention

The present invention relates to elastic wave devices that utilize longitudinal wave leaky elastic waves.

### 2. Description of the Related Art

Elastic wave devices that utilize longitudinal wave leaky elastic waves have been known to date. For example, Japanese Unexamined Patent Application Publication No. 2004-135267 discloses an elastic wave device in which an IDT electrode made from an Au film is provided on a LiNbO₃ substrate with specific Euler angles. This elastic wave device may enable an increase in electromechanical coupling coefficient, a reduction in propagation loss, and a higher phase velocity by Euler angles being set in specific ranges.

Compared to other elastic waves, longitudinal wave leaky elastic waves are relatively high in phase velocity. Thus, use of the elastic wave device described in Japanese Unexamined Patent Application Publication No. 2004-135267 brings adaptability to higher frequencies to some extent. However, the extent of the adaptability is limited. Further, a fractional band and an impedance ratio may be insufficient.

In addition, since longitudinal wave leaky elastic waves are in a mode of propagating while leaking, a Q factor that is sufficiently large may not be able to be obtained.

### SUMMARY OF THE INVENTION

Preferred embodiments of the present invention provide elastic wave devices that use longitudinal wave leaky elastic waves, are able to achieve higher frequencies, and have favorable characteristics including a fractional band, impedance ratio, and Q factor.

An elastic wave device according to a preferred embodiment of the present invention utilizes longitudinal wave leaky elastic wave and includes a piezoelectric layer including a first principal surface and a second principal surface that face each other; an IDT electrode provided on the first principal surface or the second principal surface of the piezoelectric layer; and an energy confinement layer that is laminated on the second principal surface of the piezoelectric layer so as to support the piezoelectric layer and confine energy of the longitudinal wave leaky elastic wave in the piezoelectric layer, a thickness of the piezoelectric layer being λ or less when λ represents a wavelength determined according to an electrode finger pitch of the IDT electrode, a groove being provided in a principal surface that is included in the first principal surface and the second principal surface of the piezoelectric layer and is provided with the IDT electrode, the IDT electrode including a portion disposed in the groove.

The longitudinal wave leaky elastic wave is an elastic wave in which longitudinal wave components are dominant as compared to transversal wave components, or pseudo elastic wave in which longitudinal wave components are dominant as compared to transversal wave components. The longitudinal wave leaky elastic wave is in a mode of propagating while leaking energy.

In an elastic wave device according to a preferred embodiment of the present invention, a depth of the groove may be less than a half of the thickness of the piezoelectric layer. In this case, the influence of the groove on the durability of the piezoelectric layer is decreased and thus, the durability of the piezoelectric layer is improved.

In an elastic wave device according to a preferred embodiment of the present invention, about 60% or more of the IDT electrode may be disposed in the groove. In this case, filter characteristics of the elastic wave device are further improved.

In an elastic wave device according to a preferred embodiment of the present invention, about 60% to about 80% of the IDT electrode may be disposed in the groove. In this case, characteristics relating to a fractional band, which are included in the filter characteristics of the elastic wave device, are further improved.

In an elastic wave device according to a preferred embodiment of the present invention, the piezoelectric layer may have a crystal orientation with natural unidirectionality. That is, a piezoelectric layer that has Euler angles different than Euler angles (0°, θ, 0°) and (90°, 90°, ψ) is used. With these crystal orientations, a stop band may cause a spurious response. However, the IDT electrode is provided in the groove of the piezoelectric layer and, thus, the spurious response is effectively reduced or prevented.

The crystal orientation with natural unidirectionality may be a crystal orientation in which Euler angles are different than (0°, θ, 0°) and (90°, 90°, ψ).

In an elastic wave device according to a preferred embodiment of the present invention, the groove may include a pair of side surfaces and a bottom surface, and the pair of side surfaces may be inclined surfaces so that a distance between the pair of side surfaces increases as the distance increases from the bottom surface. In this case, the IDT electrode is structured to easily come into contact with the bottom surface and side surfaces of the groove.

In an elastic wave device according to a preferred embodiment of the present invention, Euler angles of the piezoelectric layer may be (within about 90°±5° range, within about 90°±5° range, within about 40°±25° range).

In an elastic wave device according to a preferred embodiment of the present invention, the groove may be located toward the first principal surface of the piezoelectric layer and the IDT electrode may be located toward the first principal surface. In this case, the groove and IDT electrode are easily provided.

In an elastic wave device according to a preferred embodiment of the present invention, the energy confinement layer may include a high acoustic velocity material layer in which an acoustic velocity of a propagating bulk wave is higher than an acoustic velocity of an elastic wave propagating through the piezoelectric layer, and a low acoustic velocity material layer that is positioned between the piezoelectric layer and the high acoustic velocity material layer, and in which an acoustic velocity of a propagating bulk wave is lower than the acoustic velocity of the elastic wave propagating through the piezoelectric layer.

In this case, the energy of the elastic wave is effectively confined in the piezoelectric layer. The high acoustic velocity material layer may be a support substrate made from a high acoustic velocity material.

Additionally, a support substrate laminated on a surface that is included in the energy confinement layer and is on an opposite side of the piezoelectric layer may be further included.

In an elastic wave device according to a preferred embodiment of the present invention, the energy confinement layer may be an acoustic reflection film and the acoustic reflection film may include a low acoustic impedance layer that is relatively low in acoustic impedance and a high acoustic impedance layer that is laminated on the low acoustic impedance layer and is higher in acoustic impedance than the low acoustic impedance layer. In this case, the energy of the elastic wave is effectively confined in the piezoelectric layer.

In an elastic wave device according to a preferred embodiment of the present invention, the energy confinement layer may be a space holding layer below a region of the piezoelectric layer in which the IDT electrode is provided and includes space toward the second principal surface of the piezoelectric layer. Also in this case, the energy of the elastic wave is effectively confined in the piezoelectric layer.

In an elastic wave device according to a preferred embodiment of the present invention, the space holding layer may be a support substrate with a top surface that includes a depression, the top surface of the support substrate may be laminated on the second principal surface of the piezoelectric layer, and the depression may define the space.

In an elastic wave device according to a preferred embodiment of the present invention, the IDT electrode may include a metal layer made from a metal selected from Al, Cu, and Ti, and an alloy predominantly including the Al, the Cu, or the Ti.

In an elastic wave device according to a preferred embodiment of the present invention, the IDT electrode may be made from the Al or an alloy predominantly including the Al.

In an elastic wave device according to a preferred embodiment of the present invention, the piezoelectric layer may be made from lithium niobate or lithium tantalate.

In an elastic wave device according to a preferred embodiment of the present invention, the energy confinement layer may include silicon oxide. In this case, frequency temperature characteristics of the elastic wave device are improved.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a front sectional view of an elastic wave device according to a first preferred embodiment of the present invention.

FIG. 2 is a schematic plan view that illustrates an electrode structure of the elastic wave device according to the first preferred embodiment of the present invention.

FIG. 3 illustrates a relationship between a groove depth and a fractional band.

FIG. 4 illustrates a relationship between a groove depth and an impedance ratio.

FIG. 5 illustrates a relationship between a groove depth and a phase velocity.

FIG. 6 illustrates a relationship between a groove depth and a phase velocity in a case in which the IDT electrode is made from Ti.

FIG. 7 illustrates a relationship between a groove depth and a phase velocity in a case in which the IDT electrode is made from Cu.

FIG. 8 illustrates a relationship between resonance characteristics of an elastic wave device according to a comparative example and a stop band.

FIG. 9 illustrates a relationship between resonance characteristics of an elastic wave device according to a first example of a second preferred embodiment of the present invention and a stop band.

FIG. 10 illustrates implementation between resonance characteristics of the elastic wave device according to a second example of the second preferred embodiment of the present invention, in which the IDT electrode is embedded in grooves by about ¾ of its thickness, and a stop band.

FIG. 11 illustrates a relationship between resonance characteristics of the elastic wave device according to a third example of the second preferred embodiment of the present invention, in which the IDT electrode is embedded in grooves by all of its thickness, and a stop band.

FIG. 12A is a front sectional view of an elastic wave device according to a third preferred embodiment of the present invention.

FIG. 12B is a front sectional view of a variation of the elastic wave device according to the third preferred embodiment of the present invention.

FIG. 13 is a front sectional view of an elastic wave device according to a fourth preferred embodiment of the present invention.

FIG. 14 is a partially cut enlarged front sectional view for describing a variation of the groove in the elastic wave device according to a preferred embodiment of the present invention.

### DETAILED DESCRIPTION OF THE PREFERRED EMBODIMENTS

Preferred embodiments of the present invention will be described below with reference to the drawings.

Each of the preferred embodiments described herein is an example and it should be noted that partial replacements or combinations of the elements are possible between different preferred embodiments.

### First Preferred Embodiment

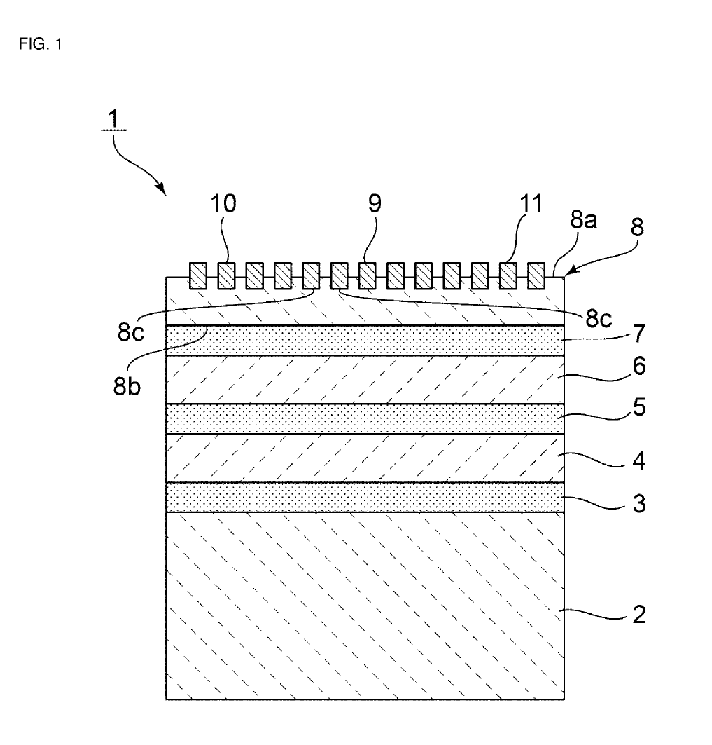

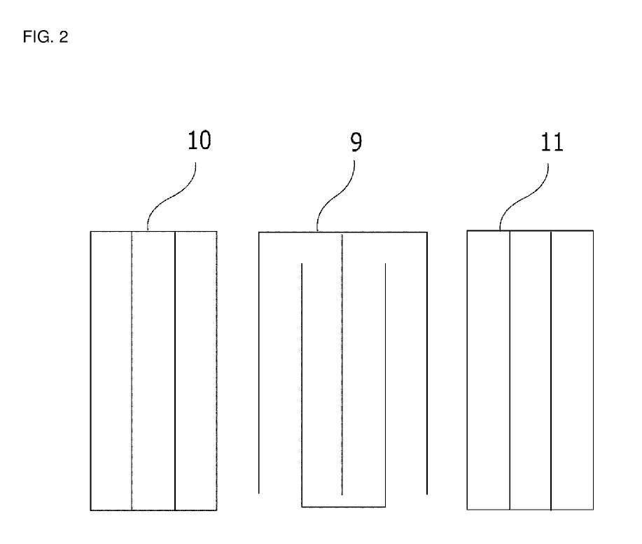

FIG. 1 is a front sectional view of an elastic wave device 1 according to a first preferred embodiment of the present invention and FIG. 2 is a schematic plan view that illustrates an electrode structure.

The elastic wave device 1 utilizes longitudinal wave type leaky elastic waves. The elastic wave device 1 includes a support substrate 2. In the present preferred embodiment, the support substrate 2 is preferably made of silicon, for example. The material for the support substrate 2 is not particularly limited, and various insulative materials, such as alumina and silicon nitride, and semiconductor materials, such as gallium arsenide, for example, may be usable.

An acoustic reflection film is laminated as an energy confinement layer over the support substrate 2. In the acoustic reflection film, low acoustic impedance layers 3, 5, and 7 and high acoustic impedance layers 4 and 6 are alternately laminated. The low acoustic impedance layers 3, 5, and 7 are lower in acoustic impedance than the high acoustic impedance layers 4 and 6. As long as this acoustic impedance relationship is satisfied, the materials for the low acoustic impedance layers 3, 5, and 7 and the high acoustic impedance layers 4 and 6 are not particularly limited.

In the present preferred embodiment, the low acoustic impedance layers 3, 5, and 7 are preferably made from SiO₂, for example. The low acoustic impedance layers 3, 5, and 7 may be made from an inorganic oxide different than SiO₂ or from metal, such as Al or Ti, for example. The high acoustic impedance layers 4 and 6 are preferably made from Pt, for example. The high acoustic impedance layers 4 and 6 may be made from W, Mo, Ta, or other suitable materials, for example.

The acoustic reflection film that includes the low acoustic impedance layers 3, 5, and 7 and the high acoustic impedance layers 4 and 6 described above is provided over the support substrate 2. A piezoelectric layer 8 is provided over the low acoustic impedance layer 7, that is, over the acoustic reflection film. The piezoelectric layer 8 is preferably made from LiNbO₃ with Euler angles of about (90°, 90°, 40°), for example. The piezoelectric layer 8 may be made from LiNbO₃ with another crystal orientation, for example. The piezoelectric layer 8 may be made from another piezoelectric single crystal, such as LiTaO₃, ZnO, or AlN, for example.

The piezoelectric layer 8 includes a first principal surface 8a and a second principal surface 8b, which face each other. The second principal surface 8b is positioned over the low acoustic impedance layer 7. The first principal surface 8a is positioned on the opposite side of the low acoustic impedance layer 7. A plurality of grooves 8c are provided in the first principal surface 8a. The plurality of grooves 8c are filled with an electrode material, and an inter-digital transducer (IDT) electrode 9 and reflectors 10 and 11 are provided.

As illustrated in FIG. 1, each groove 8c includes a bottom surface and a pair of side surfaces. The grooves 8c are filled with the electrode material. In FIG. 1, the pair of side surfaces of each groove 8c extend in a direction perpendicular or substantially perpendicular to the first principal surface 8a. That is, one of the side surface and the other side surface are parallel or substantially parallel.

Electrode finger portions of the IDT electrode 9 are illustrated, and the IDT electrode 9 projects further upward than the first principal surface 8a. In the elastic wave device 1, the IDT electrode 9 are disposed in the grooves 8c. In this case, the IDT electrode 9 may be entirely or substantially entirely embedded in the grooves 8c or as illustrated in FIG. 1, lower portions of the IDT electrode 9 may be embedded in the grooves 8c and upper portions of the IDT electrode 9 may project upward from the first principal surface 8a.

The IDT electrode 9 and the reflectors 10 and 11 may be made from a suitable metal. Such metal is not particularly limited but a metal layer made from, for example, one selected from Al, Ti, and Cu, and an alloy that predominantly includes Al, Ti, or Cu is preferably used. More preferably, Al or an alloy that predominantly includes Al is used. In this case, resistance loss is small. In the present preferred embodiment, the IDT electrode 9 and the reflectors 10 and 11 are preferably made from Al, for example.

Further, the IDT electrode 9 and the reflectors 10 and 11 may be made from a laminated metal film including a plurality of metal films that are laminated.

In the elastic wave device 1, the acoustic reflection film that includes the low acoustic impedance layers 3, 5, and 7 and the high acoustic impedance layers 4 and 6 described above defines and functions as an energy confinement layer. Since the acoustic reflection film is provided in the elastic wave device 1, the longitudinal wave leaky elastic waves that leak toward the acoustic reflection film are reflected off the acoustic reflection film. That is, the acoustic reflection film confines the longitudinal wave leaky elastic waves excited by the piezoelectric layer 8.

In addition, the thickness of the piezoelectric layer 8 is preferably, for example, λ or less, in the elastic wave device 1 and thus, when an alternating electric field is applied to the IDT electrode 9, longitudinal wave leaky elastic waves are efficiently excited and propagate through the piezoelectric layer 8. Accordingly, the longitudinal wave leaky elastic waves propagate through the piezoelectric layer 8 while having high energy intensity.

As described above, the intensity of the longitudinal wave leaky elastic waves that propagate through the piezoelectric layer 8 is increased and as a result, a Q factor is improved.

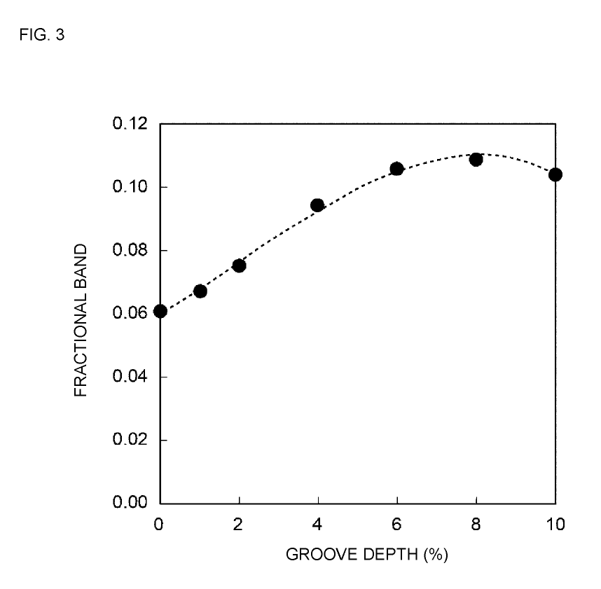

Moreover, since the IDT electrode 9 and the reflectors 10 and 11 are disposed in the grooves 8c, a fractional band and an impedance ratio are improved and higher frequencies are achieved. This is described with reference to FIGS. 3 to 5. Besides, the impedance ratio is Za-Zr (dB) when the impedance of the antiresonant frequency of an elastic wave resonator is Za (dB) and the impedance of the resonance frequency of the elastic wave resonator is Zr (dB).

How a fractional band, an impedance ratio, and a phase velocity vary in the elastic wave device 1 when the groove depth of each groove 8c is changed is illustrated in FIGS. 3 to 5.

In this case, each of the thicknesses of the SiO₂ films defining the low acoustic impedance layers 3, 5, and 7 is assumed to be about 0.09 λ, for example. Each of the thicknesses of the Pt films defining the high acoustic impedance layers 4 and 6 is assumed to be about 0.14 λ, for example. The piezoelectric layer 8 is assumed to be a LiNbO₃ film that has, for example, a thickness of about 0.2 λ and Euler angles of about (90°, 90°, 40°).

The thickness of the IDT electrode 9 is assumed to be about 0.1 λ, for example.

It is also assumed that λ represents a wavelength determined according to an electrode finger pitch of the IDT electrode 9 and λ=about 1.7 μm, for example.

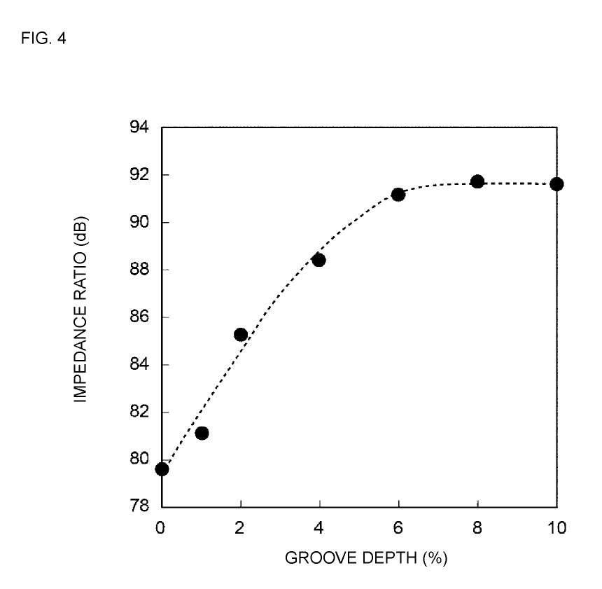

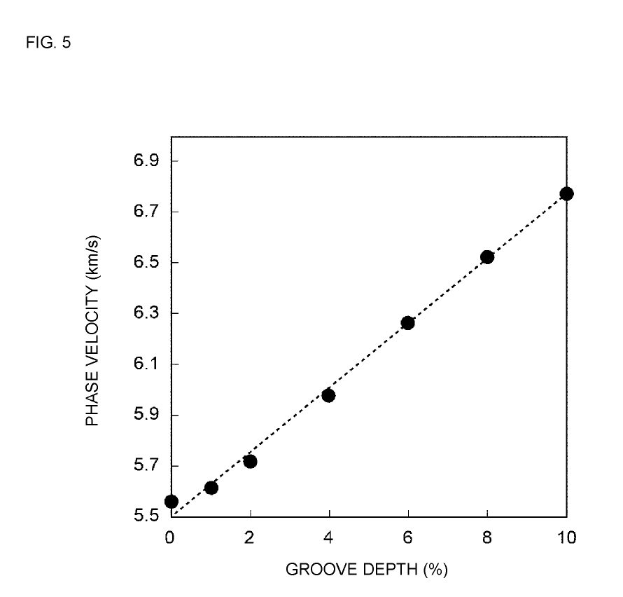

FIG. 3 illustrates a relationship between a groove depth (%) and a fractional band, FIG. 4 illustrates a relationship between a groove depth (%) and an impedance ratio, FIG. 5 illustrates a relationship between a groove depth (%) and a phase velocity.

The groove depth in each of FIGS. 3 to 5 is indicated in % using the ratio of the depth of each groove 8c to a wavelength λ. Thus, the groove depth being substantially 0% in FIG. 3, 4, or 5 indicates that no grooves 8c are provided and a result of a structure outside the range of the present invention. In contrast, the groove depth being substantially 10% indicates that the IDT electrode 9 is entirely or substantially entirely embedded in the grooves 8c in the thickness direction since the thickness of the IDT electrode 9 is about 0.1 λ. Thus, the first principal surface 8a of the piezoelectric layer 8 is flush or substantially flush with the top surface the IDT electrode 9.

As FIG. 3 demonstrates, as compared to a case in which no grooves 8c are provided, the fractional band is increased by a portion or all of the IDT electrode 9 being disposed in the grooves 8c. In particular, when the groove depth is about 6% or more, that is, when about 6/10=3/5 or more of the IDT electrode 9 is disposed in the grooves 8c, the fractional band is large, which is about 0.10 or more. Thus, it is preferable that the IDT electrode is disposed in the grooves 8c by about 3/5 or more of its thickness, for example. It was discovered that when the groove depth is larger than about 8%, that is, more than about 8/10 (80%) of the IDT electrode 9 is disposed in the grooves 8c, the value of the fractional band starts to decrease. Thus, it is more preferable that about 80% or less of the IDT electrode is disposed in the grooves 8c.

As illustrated in FIG. 4, as compared to a case in which no grooves 8c are provided, the impedance ratio is increased when a portion or all of the IDT electrode is disposed in the grooves 8c. The impedance ratio is a ratio of the impedance of anti-resonant frequency to the impedance of resonant frequency in resonance characteristics.

As illustrated in FIG. 4, as compared to a case in which no grooves 8c are provided, it can be seen that the impedance ratio is effectively increased by a portion or all of the IDT electrode 9 being disposed in the grooves. Preferably, the groove depth is about 6% or more, for example. That is, when the IDT electrode 9 is disposed in the grooves 8c by about 3/5 or more of its thickness, the impedance ratio is high, which is about 91 dB or more, for example. It can be seen that when the groove depth varies in ratio between about 6% or more and 10% or less, variation in impedance ratio is also small. Thus, in view of the impedance ratio, it is preferable that the IDT electrode 9 is disposed in the grooves 8c by about 3/5 or more of its thickness.

As illustrated in FIG. 5, as compared to a case in which no grooves 8c are provided, the phase velocity rises as the depth of each groove 8c increases. Thus, adaptability to higher frequencies is provided by a portion or all of the IDT electrode 9 being disposed in the grooves 8c. In particular, it can be seen that higher frequencies are further promoted by more thickness portions of the IDT electrode 9 being disposed in the grooves.

Longitudinal wave leaky elastic waves are distinguished in that their phase velocity is higher than those of Rayleigh waves and SH waves. Thus, a rise in phase velocity results in higher frequencies of a device being produced. In addition, in the present preferred embodiment, a fractional band is increased and an impedance ratio is increased by a portion or all of the IDT electrode 9 being disposed in the grooves. Accordingly, an increase in the fractional band facilitates an increase in the pass band in an application to a filter. Further, an impedance ratio is able to be raised and thus, a filter is provided that achieves small loss and large out-of-band attenuation.

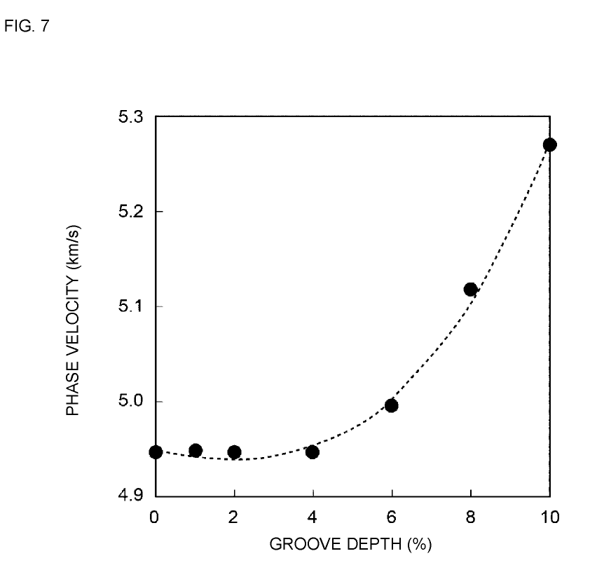

Although Al is used as the electrode material in FIGS. 3 to 5, FIG. 6 illustrates a relationship between the groove depth and the phase velocity in a case in which Ti is used as the electrode material. FIG. 7 illustrates a relationship between the groove depth and the phase velocity in a case in which Cu is used as the electrode material. In any of the cases, the elastic wave device 1 is configured so as to be similar to those in the cases illustrated in FIGS. 3 to 5, except the electrode material.

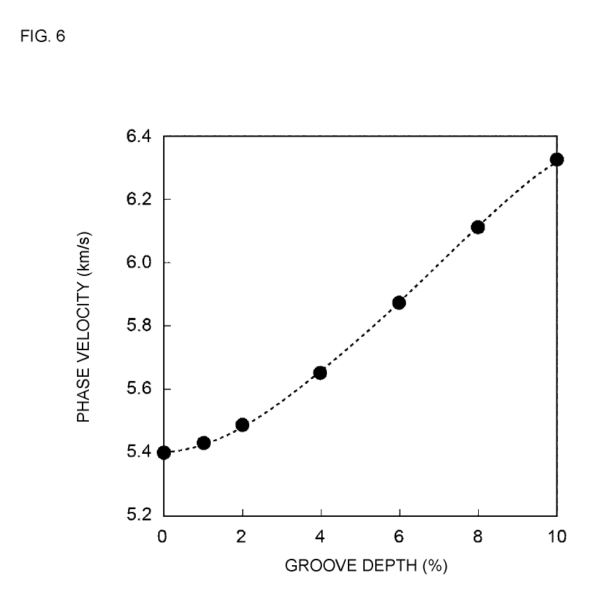

As FIGS. 6 and 7 demonstrate, even when the electrode material is changed to Ti or Cu, as compared to a case in which no grooves 8c are provided, the phase velocity is increased by a portion or all of the IDT electrode 9 being disposed in the grooves 8c. In particular, it can be seen that the phase velocity is effectively increased as the groove depth increases.

As illustrated in FIG. 7, it can be seen that when the electrode material is Cu, it is preferable that the groove depth be about 6% or more, that is, the IDT electrode 9 is disposed in the grooves by about 3/5 or more of its thickness so as to effective increase the phase velocity.

As the results in FIGS. 6 and 7 demonstrate, even when another electrode material is used, similar to the case in which Al is used, higher frequencies are achieved by providing the IDT electrode so that the IDT electrode is disposed in the grooves 8c provided in the piezoelectric layer 8.

Since the piezoelectric layer needs to have a very small thickness, which is preferably, for example, about 1 λ or less, so as to excite longitudinal wave leaky elastic waves, the grooves may adversely affect the durability of the piezoelectric layer. Thus, the influence of the grooves on the durability of the piezoelectric layer is decreased by making the depth of each groove less than about a half of the thickness of the piezoelectric layer and thus, the durability of the piezoelectric layer is improved.

Although LiNbO₃ with Euler angles of about (90°, 90°, 40°) is preferably used in the elastic wave device 1, Euler angles of about (90°±5°, 90°±5° range, within 40°±25° range) may similarly cause favorable excitement of longitudinal wave type leaky elastic waves. Thus, a preferable Euler Angle range is about (within 90°±5° range, within 90°±5° range, within 40°±25° range), for example.

### Second Preferred Embodiment

An elastic wave device according to a second preferred embodiment of the present invention is prepared as described below. Except that a LiNbO₃ film with Euler angles of about (0°, 35°, 90°) is used as a piezoelectric layer 8, the elastic wave device according to the second preferred embodiment is prepared in the same or similar manner to that for the elastic wave device that obtains the characteristics illustrated in FIGS. 3 to 5.

The LiNbO₃ with Euler angles of about (0°, 35°, 90°) has a crystal orientation with natural unidirectionality. The crystal orientation with natural unidirectionality is a crystal orientation in which the Euler angles are substantially different than (0°, θ, 0°) and (90°, 90°, ψ). When a piezoelectric layer having a crystal orientation with natural unidirectionality is used, a problem of a spurious response caused by a stop band may occur.

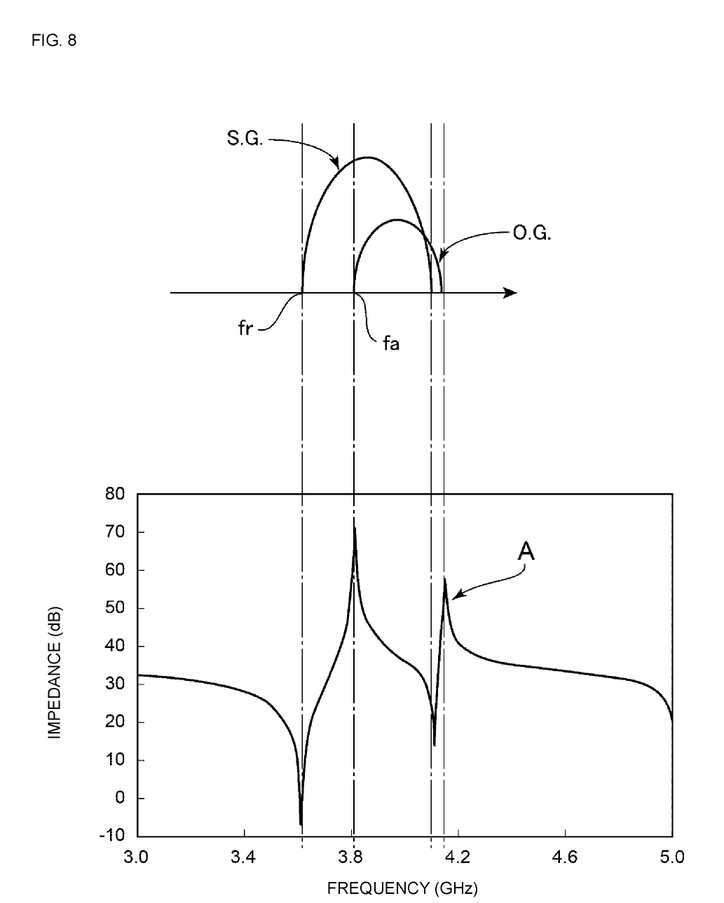

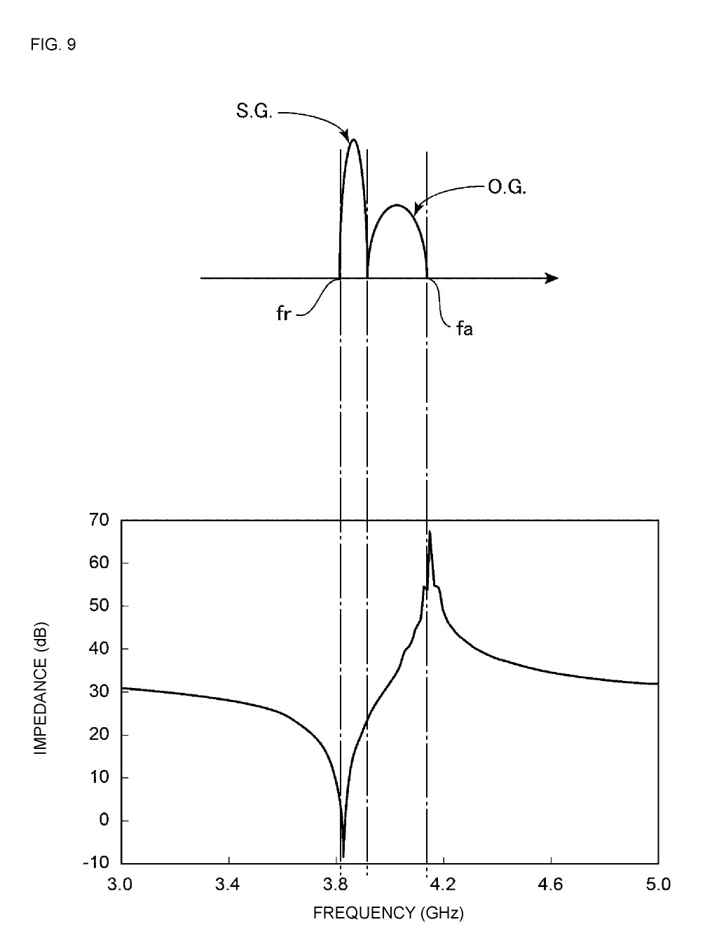

In the elastic wave device according to the second preferred embodiment, similar to the first preferred embodiment, grooves 8c are provided in the piezoelectric layer 8 and at least a portion of an IDT electrode is disposed in the grooves 8c, and an acoustic reflection film as an energy confinement layer is laminated. Thus, even when a piezoelectric layer having a crystal orientation with the above-described natural unidirectionality is used as the piezoelectric layer 8, the spurious response caused by the stop band is effectively reduced or prevented. This is described with reference to FIGS. 8 and 9.

As a first example of the second preferred embodiment, the elastic wave device that is described below is prepared.

Support substrate 2: silicon

Low acoustic impedance layers 3, 5, and 7: SiO₂ film with thickness of about 0.09 λ

High acoustic impedance layers 4 and 6: Pt film with thickness of about 0.14 λ

Piezoelectric layer 8: LiNbO₃ with Euler angles of about (0°, 35°, 90°) and with a thickness of about 0.2 λ, depth of groove 8c=about 0.04 λ

IDT electrode 9 and reflectors 10 and 11: Al film with thickness of about 0.08 λ

Wavelength λ determined according to electrode finger pitch=about 1.7 μm.

The IDT electrode 9 and the reflectors 10 and 11 are disposed in the grooves 8c by about 1/2 of the electrode thickness.

As a comparative example 1, except that no grooves 8c are provided, an elastic wave device having the same or similar structure to that according to the first preferred embodiment is prepared.

FIG. 8 illustrates a relationship between resonance characteristics of the elastic wave device according to the comparative example 1 and a stop band. In the upper portion of FIG. 8, two electrical conditions of cases in which a grating electrode electrically establishes a short circuit (S.G.) and is electrically opened (O.G.) are illustrated. In the lower portion of FIG. 8, a relationship between frequencies at which lower-frequency stop band end portions and higher-frequency stop band end portions are positioned and resonance characteristics under the respective electrical conditions described above is illustrated.

When the piezoelectric layer has no natural unidirectionality, one stop band end portion of the lower-frequency and higher-frequency stop band end portions in S.G. and one stop band end portion of the lower-frequency and higher-frequency stop band end portions in O.G. match.

In this case, at a frequency at which the matching stop band end portions are positioned, no resonance occurs and no resonant frequency or anti-resonant frequency is produced. In contrast, at frequencies at which mismatching stop band end portions are positioned, resonance occurs and a frequency at which a lower-frequency stop band end portion of the mismatching stop band end portions is positioned defines and functions as a main resonant frequency (fr) of an elastic wave resonator and a frequency at which a higher-frequency stop band end portion of the mismatching stop band end portions is positioned defines and functions as a main anti-resonant frequency (fa). Accordingly, when the piezoelectric layer has natural unidirectionality, resonance characteristics different than the main resonance characteristics do not appear and no spurious response is produced.

When the piezoelectric layer has natural unidirectionality, stop band end portions exhibit no matching unlike the case described above. That is, at frequencies at which all of stop band end portions of S.G. and O.G. are positioned, a resonant frequency or an anti-resonant frequency occurs. Thus, other resonance characteristics that are different than the resonance characteristics of the main resonant frequency (fr) and the anti-resonant frequency (fa) appear and a spurious response is produced. For example, in FIG. 8, a large spurious is produced, which arrow A indicates is caused toward higher frequencies of the main resonance characteristics.

In contrast, FIG. 9 illustrates a relationship between resonance characteristics of the elastic wave device according to the first example and a stop band. In FIG. 9, the higher-frequency stop band end portion of the stop band end portions in S.G. and the lower-frequency stop band end portion of the stop band end portions in O.G. approximately match. Thus, a spurious response in a stop band end portion hardly occurs on the resonance characteristics.

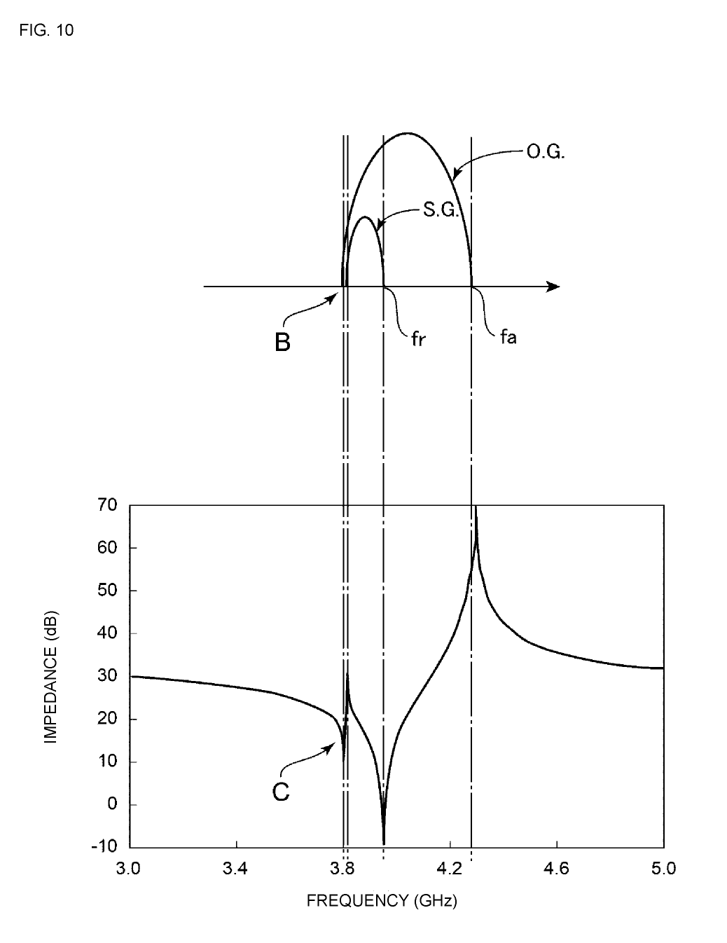

FIG. 10 illustrates a relationship between resonance characteristics of the elastic wave device according to a second example of the second preferred embodiment and a stop band.

The second example is similar to the first example except that the IDT electrode 9 is disposed in the grooves 8c by about 3/4 of the electrode thickness of the IDT electrode. Although, in FIG. 10, the lower-frequency stop band end portion of the stop band end portions in S.G. and the lower-frequency stop band end portion of the stop band end portions in O.G. slightly deviate from each other as arrow B indicates, the deviation between the stop band end portions is small as compared to the comparative example 1. In the comparative example 1 illustrated in FIG. 8, a spurious response A is caused toward higher frequencies of a main response. In contrast, in the second example, a spurious response C is able to be moved toward lower frequencies than the main response and the magnitude of the spurious response C is able to be made sufficiently small. Accordingly, a spurious response can be made small and a frequency at which a spurious occurs can be moved by selecting the ratio of embedding when a portion or all of the IDT electrode 9 is embedded in the grooves 8c. Thus, depending on demanded characteristics, an elastic wave device is able to be easily designed.

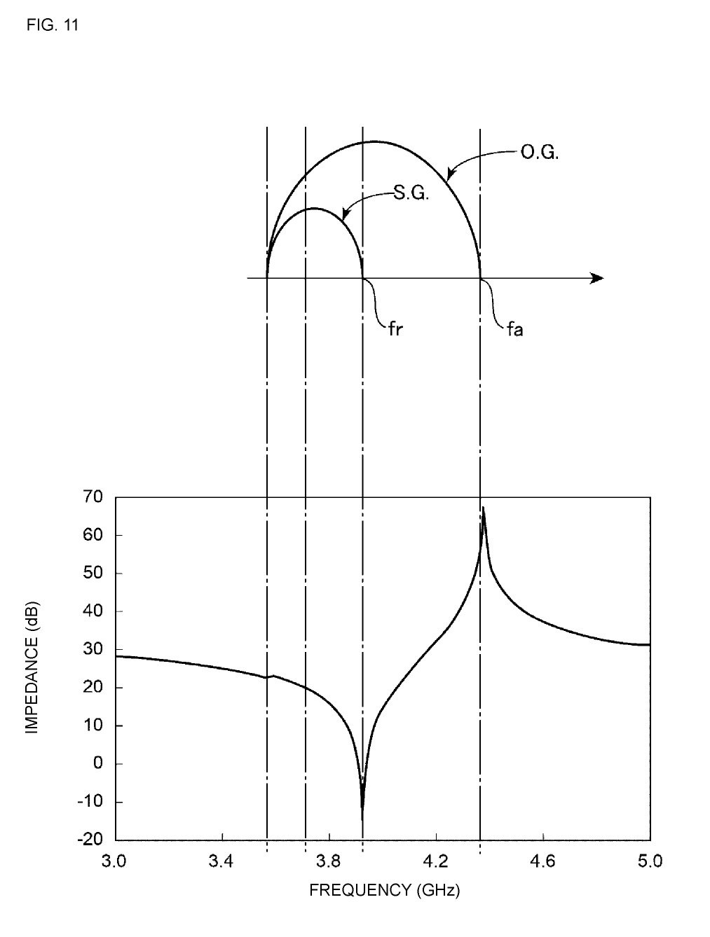

FIG. 11 illustrates a relationship between resonance characteristics of the elastic wave device according to a third example of the second preferred embodiment and a stop band. The configuration according to the third example is similar to those according to the first example and the second example of the second preferred embodiment, except that the IDT electrode 9 is embedded in the grooves 8c by all or substantially all of the thickness of the IDT electrode 9.

As FIG. 11 demonstrates, more favorable resonance characteristics are able to be obtained when the IDT electrode 9 is embedded in the grooves 8c in the overall thickness direction of the IDT electrode 9. This is because as illustrated in FIG. 11, a deviation between the lower-frequency stop band end portion of the stop band end portions in S.G. and the lower-frequency stop band end portion of the stop band end portions in O.G. is further decreased than that in the second example.

The results of the above-described first to third examples of the second preferred embodiment demonstrate that also when a piezoelectric layer with natural unidirectionality is used, a spurious response caused by mismatching of stop band end portions is effectively reduced or prevented by the energy confinement layer and the grooves 8c. That is, favorable resonance characteristics are able to be easily obtained.

Although in the second preferred embodiment, Euler angles of about (0°, 35°, 90°), for example, are preferably used, the Euler angles are not limited to this crystal orientation and various crystal orientations may be used as long as the crystal orientation has natural unidirectionality.

Although in the first to third examples of the second preferred embodiment, similar to the first preferred embodiment, an electrode made from Al is preferably used, Ti, Cu, or other suitable material, for example, may also be used. Further, not only Al, Cu, or Ti but various kinds of metal, such as Mo, Pt, W, and C, for example, may also be used. Moreover, an alloy that predominantly includes metal, such as Al, Ti, Cu, Mo, Pt, or W, for example, may also be used.

### Third Preferred Embodiment

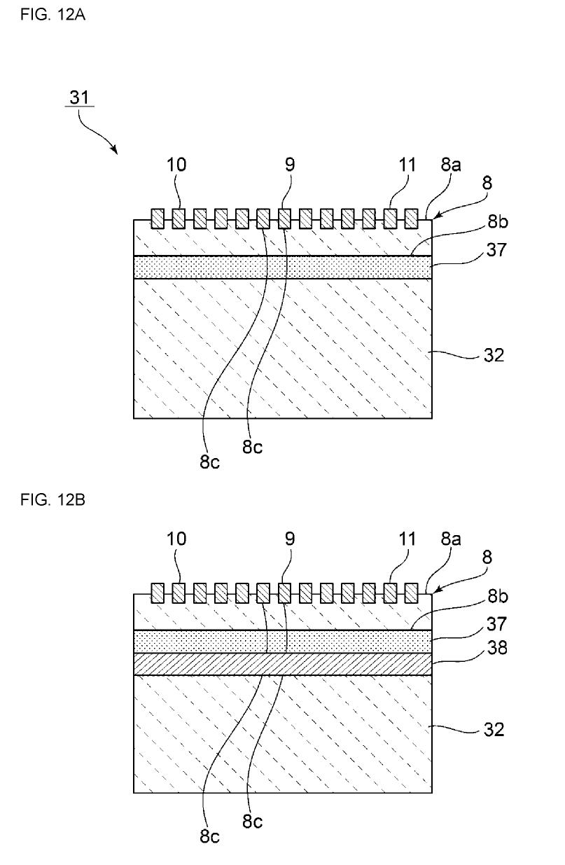

FIG. 12A is a front sectional view of an elastic wave device 31 according to a third preferred embodiment of the present invention. In the elastic wave device 31, a low acoustic velocity material layer 37 is laminated over a support substrate 32 made from a high acoustic velocity material layer. The support substrate 32 made from the high acoustic velocity material layer and the low acoustic velocity material layer 37 define an energy confinement layer. A piezoelectric layer 8 is laminated over the low acoustic velocity material layer 37 from the side of the second principal surface 8b. The piezoelectric layer 8, an IDT electrode 9, and reflectors 10 and 11 are structured so as to be similar to those in the elastic wave device 1 according to the first preferred embodiment. A difference is that the low acoustic velocity material layer 37 is provided over the support substrate 32 made from the high acoustic velocity material layer. The high acoustic velocity material is herein a material in which the acoustic velocity of propagating bulk waves is higher than the acoustic velocity of elastic waves propagating through the piezoelectric layer 8. In the present preferred embodiment, the support substrate 32 is preferably made as a silicon substrate, for example. As the material for the support substrate 32, aluminum nitride, silicon carbide, silicon nitride, and other suitable materials, for example, may be used.

The low acoustic velocity material is a material in which the acoustic velocity of propagating bulk waves is lower than the acoustic velocity of elastic waves propagating through the piezoelectric layer 8. In the present preferred embodiment, the low acoustic velocity material layer 37 is preferably made from SiO₂, for example. As the low acoustic velocity material layer 37, instead, compounds resulting by adding fluorine, carbon, or boron to SiO₂ (silicon oxide), silicon oxynitride, or tantalum oxide, glass, and other suitable materials, for example, may also be used.

That is, the elastic wave device 31 according to the third preferred embodiment is structured so as to be similar to the elastic wave device 1 according to the first preferred embodiment except that the energy confinement layer includes the support substrate 32 made from the high acoustic velocity material layer and the low acoustic velocity material layer 37.

The structure in which the support substrate 32 made from a high acoustic velocity material and the low acoustic velocity material layer 37 are laminated as described above and the property of energy becoming concentrated to a medium that is substantially low in the acoustic velocity of elastic waves reduce or prevent leakage of elastic wave energy toward the outside of the IDT electrode. Accordingly, longitudinal wave leaky elastic waves are effectively confined in the piezoelectric layer 8 and a Q factor is improved by efficiently exciting the confined energy in the piezoelectric layer with a thickness of λ or less.

Also in the third preferred embodiment, at least a portion of the IDT electrode 9 is disposed in a plurality of grooves 8c provided in a first principal surface 8a of the piezoelectric layer 8 and, thus, similar to the elastic wave device 1 according to the first preferred embodiment, higher frequencies are easily achieved. Further, the elastic wave device 31 with a fractional band, impedance ratio, and Q factor that are favorable is easily provided.

Instead of the support substrate 32, as illustrated in FIG. 12B, a structure may be used, in which the support substrate 32 and a high acoustic velocity film 38 in which the acoustic velocity of propagating bulk waves is higher than the acoustic velocity of elastic waves that propagate through the piezoelectric film, such as surface acoustic waves and boundary acoustic waves, are laminated. In this case, the low acoustic velocity material layer 37 and the high acoustic velocity film 38 define and function as an energy confinement layer. In this case, the support substrate 32 may use, for example, piezoelectric bodies, such as sapphire, lithium tantalate, lithium niobate, and quartz, various ceramic materials such as alumina, magnesia, silicon nitride, aluminum nitride, silicon carbide, zirconia, cordierite, mullite, steatite, and forsterite, dielectrics such as glass or semiconductors such as silicon and gallium nitride, resin substrates, and other suitable materials. The high acoustic velocity film 38 may use, for example, various high acoustic velocity materials such as aluminum nitride, aluminum oxide, silicon carbide, silicon nitride, silicon oxynitride, a DLC film, or diamond, media predominantly composed of these materials, media predominantly composed of mixtures of these materials, and other suitable materials.

### Fourth Preferred Embodiment

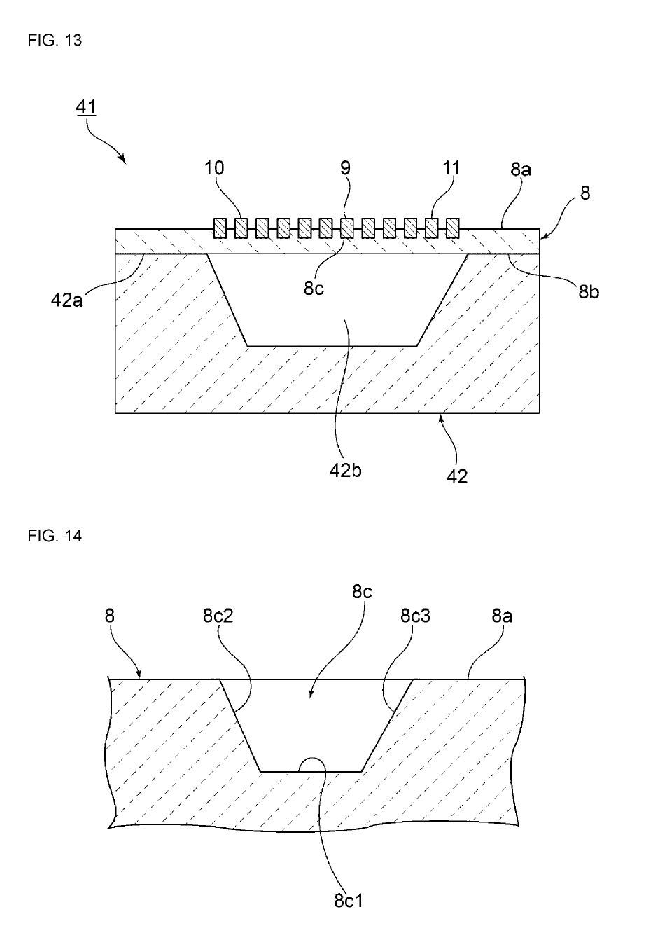

FIG. 13 is a front sectional view of an elastic wave device 41 according to a fourth preferred embodiment of the present invention. In the elastic wave device 41, a piezoelectric layer 8 is laminated over a support substrate 42. The support substrate 42 includes a top surface 42a. The top surface 42a includes a depression 42b. A region in which an IDT electrode 9 and reflectors 10 and 11 are provided is positioned over the depression 42b. That is, under the region in which the IDT electrode 9 is provided, a second principal surface 8b of the piezoelectric layer 8 is exposed to the space defined by the depression 42b. The space defined by the depression 42b defines and functions as an energy confinement layer that confines the energy of longitudinal wave leaky elastic waves in the piezoelectric layer 8 by reflection action or similar action. That is, the support substrate 42 defines a space holding layer, which holds the space.

Also in the elastic wave device 41, the IDT electrode 9 is provided so that at least a portion of the IDT electrode 9 is disposed in a plurality of grooves 8c provided in a first principal surface 8a. Thus, similar to the elastic wave device 1 according to the first preferred embodiment, higher frequencies are easily achieved. In addition, resonance characteristics are improved.

Although not illustrated, a medium film, for example, is preferably laminated over the second principal surface 8b and the medium film may be exposed to the space defined by the depression 42b. That is, the space defined by the depression 42b is provided on the side of the second principal surface 8b, but the second principal surface 8b is not necessarily exposed to the space.

The region in which the IDT electrode 9 and the reflectors 10 and 11 are provided is not limited to the position over the depression 42b. The IDT electrode 9 and the reflectors 10 and 11 may be provided over a region that is included in the top surface 42a of the support substrate 42 and in which the depression 42b is not provided. Even in this case, the advantageous effects of preferred embodiments of the present invention are obtained.

FIG. 14 illustrates a variation of the groove 8c provided in the piezoelectric layer 8 according to a preferred embodiment of the present invention. As illustrated in FIG. 14, the groove 8c includes a bottom surface 8c1 and a pair of side surfaces 8c2 and 8c3. Upper ends of the side surfaces 8c2 and 8c3 are substantially continuous with the first principal surface 8a. The distance between the side surface 8c2 and the side surface 8c3 increases as the distance from the bottom surface 8c1 increases. Since the side surfaces 8c2 and 8c3 are inclined surfaces, when an electrode material is embedded in the groove 8c, the groove 8c is certainly filled with the electrode material and an air gap is unlikely to be provided. Since the interior angle between the side surface 8c2 or the side surface 8c3 and the bottom surface 8c1 is preferably an obtuse angle, the groove 8c is certainly filled with the electrode material.

In the elastic wave devices according to preferred embodiments of the present invention, it is preferable that the energy confinement layer includes silicon oxide. For example, in each elastic wave device according to the first to third preferred embodiments, it is preferable that the low acoustic impedance layer and the low acoustic velocity material layer be made from silicon oxide. For another example, in the first to third preferred embodiments, layers other than the low acoustic velocity material layers may include silicon oxide. Also in the fourth preferred embodiment, as described above, a medium may be laminated on the second principal surface 8b of the piezoelectric layer 8 and it is preferable that a silicon oxide film, for example, be used as the medium. In this case, the support substrate 42 and the medium made of the silicon oxide film, which are described above, define a space holding layer as an energy confinement layer. It is thus preferable that the energy confinement layer include silicon oxide in a variety of structures as described above, and frequency temperature characteristics of an elastic wave device are improved accordingly.

Although an elastic wave resonator is described in each of the above-described preferred embodiments, the present invention is applicable to an elastic wave device having an electrode structure different than the elastic wave resonator.

Although SiO₂ is used as an example of silicon oxide and LiNbO₃ and LiTaO₃ are used as examples of lithium niobate and lithium tantalate, respectively, in each of the above-described preferred embodiments, the usable compounds are not limited to the compounds of the compositions having with the above-described chemical formulas.

Although each of the above-described preferred embodiments describes only advantages brought when the top surface of the IDT electrode is higher than a principal surface of the piezoelectric layer or when the top surface of the IDT electrode is flush or substantially flush with a principal surface of the piezoelectric layer, advantages of the present invention may also be obtained when the top surface of the IDT electrode is lower than a principal surface of the piezoelectric layer.

While preferred embodiments of the invention have been described above, it is to be understood that variations and modifications will be apparent to those skilled in the art without departing from the scope and spirit of the invention. The scope of the invention, therefore, is to be determined solely by the following claims.

What is claimed is:

1. An elastic wave device that utilizes longitudinal wave leaky elastic wave, comprising:
a piezoelectric layer including a first principal surface and a second principal surface that face each other;
an inter-digital transducer (IDT) electrode provided on one of the first principal surface and the second principal surface of the piezoelectric layer; and
an energy confinement layer that is laminated on the second principal surface of the piezoelectric layer so as to support the piezoelectric layer and confines energy of the longitudinal wave leaky elastic wave in the piezoelectric layer; wherein
a thickness of the piezoelectric layer is λ or less when λ represents a wavelength determined according to an electrode finger pitch of the IDT electrode;
a groove is provided in the one of the first principal surface and the second principal surface of the piezoelectric layer; and
the IDT electrode includes a portion disposed in the groove.

2. The elastic wave device according to claim 1, wherein a depth of the groove is less than about half of the thickness of the piezoelectric layer.

3. The elastic wave device according to claim 1, wherein about 60% or more of the IDT electrode is disposed in the groove.

4. The elastic wave device according to claim 1, wherein about 60% to about 80% of the IDT electrode is disposed in the groove.

5. The elastic wave device according to claim 1, wherein the piezoelectric layer has a crystal orientation with natural unidirectionality.

6. The elastic wave device according to claim 4, wherein the crystal orientation with the natural unidirectionality is a crystal orientation in which Euler angles are different than (0°, θ, 0°) and (90°, 90°, ψ).

7. The elastic wave device according to claim 1, wherein the groove includes a pair of side surfaces and a bottom surface, and the pair of side surfaces are inclined so that a distance between the pair of side surfaces increases as a distance from the bottom surface increases.

8. The elastic wave device according to claim 1, wherein Euler angles of the piezoelectric layer are (within 90°±5° range, within 90°±5° range, within 40°±25° range).

9. The elastic wave device according to claim 1, wherein the groove is located toward the first principal surface of the piezoelectric layer and the IDT electrode is located toward the first principal surface.

10. The elastic wave device according to claim 1, wherein the energy confinement layer includes:
a high acoustic velocity material layer in which an acoustic velocity of a propagating bulk wave is higher than an acoustic velocity of an elastic wave propagating through the piezoelectric layer; and
a low acoustic velocity material layer that is positioned between the piezoelectric layer and the high acoustic velocity material layer, and in which an acoustic velocity of propagating bulk wave is lower than the acoustic velocity of the elastic wave propagating through the piezoelectric layer.

11. The elastic wave device according to claim 10, wherein the high acoustic velocity material layer is a support substrate made from a high acoustic velocity material.

12. The elastic wave device according to claim 1, further comprising a support substrate laminated on a surface that is included in the energy confinement layer and is on an opposite side of the piezoelectric layer.

13. The elastic wave device according to claim 1, wherein
the energy confinement layer is an acoustic reflection film; and
the acoustic reflection film includes a low acoustic impedance layer that is relatively low in acoustic impedance and a high acoustic impedance layer that is laminated on the low acoustic impedance layer and higher in acoustic impedance than the low acoustic impedance layer.

14. The elastic wave device according to claim 1, wherein the energy confinement layer is a space holding layer that is disposed below a region of the piezoelectric layer in which the IDT electrode is provided, and includes a space toward the second principal surface of the piezoelectric layer.

15. The elastic wave device according to claim 14, wherein
the space holding layer is a support substrate including a top surface that includes a depression;
the top surface of the support substrate is laminated on the second principal surface of the piezoelectric layer; and
the depression defines the space.

16. The elastic wave device according to claim 1, wherein the IDT electrode includes a metal layer selected from Al, Cu, and Ti, and an alloy predominantly including the Al, the Cu, or the Ti.

17. The elastic wave device according to claim 16, wherein the IDT electrode is made from the Al or an alloy predominantly including the Al.

18. The elastic wave device according to claim 1, wherein the piezoelectric layer is made of lithium niobate or lithium tantalate.

19. The elastic wave device according to claim 1, wherein the energy confinement layer includes silicon oxide.
